(19) United States
(12) Patent Application Publication
(10) Pub. No.: US 2024/0130167 A1
(43) Pub. Date: Apr. 18, 2024

(54) DISPLAY DEVICE AND MANUFACTURING METHOD THEREOF

(71) Applicant: Japan Display Inc., Tokyo (JP)

(72) Inventor: Arichika ISHIDA, Tokyo (JP)

(73) Assignee: Japan Display Inc., Tokyo (JP)

(21) Appl. No.: 18/487,143

(22) Filed: Oct. 16, 2023

(30) Foreign Application Priority Data
Oct. 18, 2022 (JP) 2022-166927

(51) Int. Cl. H10K 59/122; H10K 59/12; H10K 59/80

(52) U.S. Cl. CPC H10K 59/122; H10K 59/1201; H10K 59/8722; H10K 2102/351

(57) ABSTRACT

According to an embodiment, a display device includes a lower electrode, a rib including a pixel aperture which overlaps the lower electrode, a partition which includes a lower portion provided on the rib, a first layer provided on the lower portion and protruding from a side surface of the lower portion, and a second layer provided on the first layer and having a width less than a width of the first layer, an organic layer which covers the lower electrode through the pixel aperture and emits light based on application of voltage, and an upper electrode which covers the organic layer and is in contact with the side surface of the lower portion.

### CROSS-REFERENCE TO RELATED APPLICATIONS

This application is based upon and claims the benefit of priority from Japanese Patent Application No. 2022-166927, filed Oct. 18, 2022, the entire contents of which are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer.

When such a display device is manufactured, a technique which improves the yield of the manufacturing process is required.

### BRIEF DESCRIPTION OF THE DRAWINGS

FIG. 1 is a diagram showing a configuration example of a display device according to an embodiment.

FIG. 2 is a diagram showing an example of the layout of subpixels.

FIG. 3 is a schematic cross-sectional view of the display device along the III-III line of FIG. 2.

FIG. 4 is a schematic cross-sectional view of the display device along the IV-IV line of FIG. 2.

FIG. 5 is a flowchart showing an example of the manufacturing method of the display device.

FIG. 6 is a schematic cross-sectional view showing part of the manufacturing process of the display device.

FIG. 7 is a schematic cross-sectional view showing a manufacturing process following FIG. 6.

FIG. 8 is a schematic cross-sectional view showing a manufacturing process following FIG. 7.

FIG. 9 is a schematic cross-sectional view showing a manufacturing process following FIG. 8.

FIG. 10 is a schematic cross-sectional view showing a manufacturing process following FIG. 9.

FIG. 11 is a schematic cross-sectional view showing a manufacturing process following FIG. 10.

FIG. 12 is a schematic cross-sectional view showing a manufacturing process following FIG. 11.

FIG. 13 is a schematic diagram showing an example of the evaporation method of an upper electrode.

FIG. 14 is a schematic cross-sectional view showing a manufacturing process following FIG. 12.

FIG. 15 is a schematic cross-sectional view showing a manufacturing process following FIG. 14.

FIG. 16 is a schematic cross-sectional view showing a manufacturing process following FIG. 15.

FIG. 17 is a schematic cross-sectional view showing a manufacturing process following FIG. 16.

FIG. 18 is a schematic cross-sectional view showing a manufacturing process following FIG. 17.

FIG. 19 is a schematic cross-sectional view of a partition according to a modified example.

### DETAILED DESCRIPTION

In general, according to one embodiment, a display device comprises a lower electrode, a rib comprising a pixel aperture which overlaps the lower electrode, a partition which includes a lower portion provided on the rib, a first layer provided on the lower portion and protruding from a side surface of the lower portion, and a second layer provided on the first layer and having a width less than a width of the first layer, an organic layer which covers the lower electrode through the pixel aperture and emits light based on application of voltage, and an upper electrode which covers the organic layer and is in contact with the side surface of the lower portion.

According to another embodiment, a manufacturing method of a display device includes forming a lower electrode, forming a rib comprising a pixel aperture which overlaps the lower electrode, forming a partition which includes a lower portion provided on the rib, a first layer provided on the lower portion and protruding from a side surface of the lower portion, and a second layer provided on the first layer and having a width less than a width of the first layer, forming an organic layer which covers the lower electrode through the pixel aperture and emits light based on application of voltage, and forming an upper electrode which covers the organic layer and is in contact with the side surface of the lower portion.

These configurations can provide a display device which can improve the yield of the manufacturing process.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

When the position of an element located in the positive direction of the Z-axis relative to another element is referred to, the term “on” or “above” may be used. When the position of an element located on the opposite direction is referred to, the term “under” or “below” may be used. When the positional relationship between two elements is defined using the terms “on”, “above”, “under”, “below”, “face”, etc., the two elements may be directly in contact with each other, or may be spaced apart from each other as a gap or another element is interposed between them.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

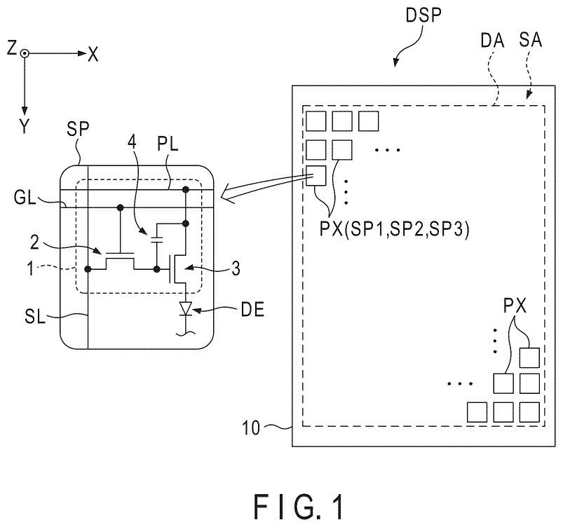

FIG. 1 is a diagram showing a configuration example of a display device DSP according to an embodiment. The display device DSP comprises a display area DA which displays an image and a surrounding area SA around the display area DA on an insulating substrate 10. The substrate 10 may be glass or a resinous film having flexibility.

In the present embodiment, the substrate 10 is rectangular as seen in plan view. It should be noted that the shape of the substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes a blue subpixel SP1, a green subpixel SP2 and a red subpixel SP3. Each pixel PX may include a subpixel SP which exhibits another color such as white in addition to subpixels SP1, SP2 and SP3 or instead of one of subpixels SP1, SP2 and SP3. Each pixel PX may consist of two subpixels SP or four or more subpixels SP.

Each subpixel SP comprises a pixel circuit 1 and a display element DE driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the display element DE. The display element DE is an organic light emitting diode (OLED) as a light emitting element.

It should be noted that the configuration of the pixel circuit 1 is not limited to the example shown in the figure. For example, the pixel circuit 1 may comprise more thin-film transistors and capacitors.

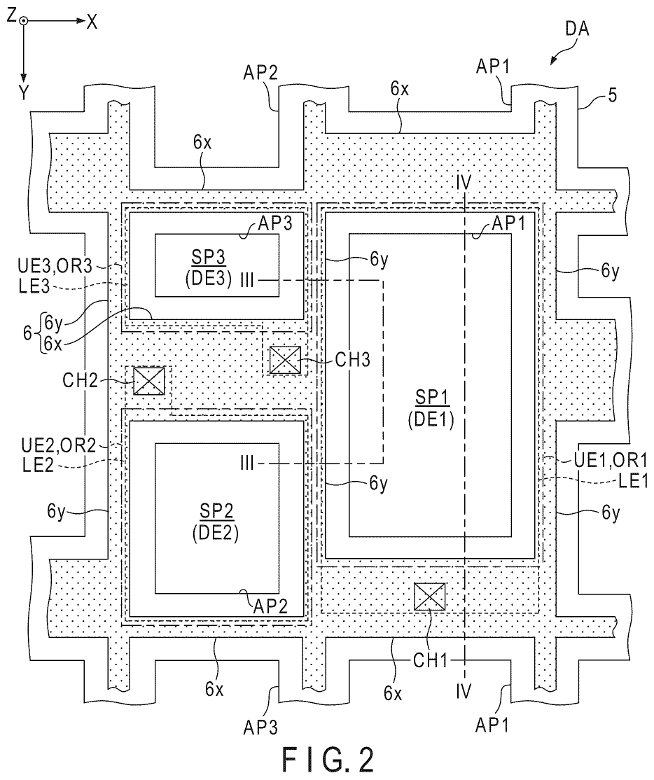

FIG. 2 is a diagram showing an example of the layout of subpixels SP1, SP2 and SP3. In the example of FIG. 2, subpixels SP1 and SP2 are arranged in the first direction X. Subpixels SP1 and SP3 are also arranged in the first direction X. Further, subpixels SP2 and SP3 are arranged in the second direction Y.

When subpixels SP1, SP2 and SP3 are provided in line with this layout, in the display area DA, a column in which subpixels SP2 and SP3 are alternately provided in the second direction Y and a column in which a plurality of subpixels SP1 are repeatedly provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises a pixel aperture AP1 in subpixel SP1, comprises a pixel aperture AP2 in subpixel SP2 and comprises a pixel aperture AP3 in subpixel SP3.

In the example of FIG. 2, the area of the pixel aperture AP1 is greater than that of the pixel aperture AP2. The area of the pixel aperture AP1 is greater than that of the pixel aperture AP3. Further, the area of the pixel aperture AP3 is less than that of the pixel aperture AP2.

The partition 6 is provided in the boundary between adjacent subpixels SP and overlaps the rib 5 as seen in plan view. The partition 6 comprises a plurality of first partitions 6x extending in the first direction X and a plurality of second partitions 6y extending in the second direction Y. The first partitions 6x are provided between the pixel apertures AP2 and AP3 which are adjacent to each other in the second direction Y and between two pixel apertures AP1 which are adjacent to each other in the second direction Y. Each second partition 6y is provided between the pixel apertures AP1 and AP2 which are adjacent to each other in the first direction X and between the pixel apertures AP1 and AP3 which are adjacent to each other in the first direction X.

In the example of FIG. 2, the first partitions 6x and the second partitions 6y are connected to each other. In this configuration, the partition 6 has a grating shape surrounding the pixel apertures AP1, AP2 and AP3 as a whole. In other words, the partition 6 comprises apertures in subpixels SP1, SP2 and SP3 in a manner similar to that of the rib 5.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the contact holes CH2 and CH3 entirely overlap the first partition 6X between the pixel apertures AP2 and AP3 which are adjacent to each other in the second direction Y. The contact hole CH1 entirely overlaps the first partition 6x between two pixel apertures AP1 which are adjacent to each other in the second direction Y. As another example, at least part of the contact hole CH1, CH2 or CH3 may not overlap the first partition 6x.

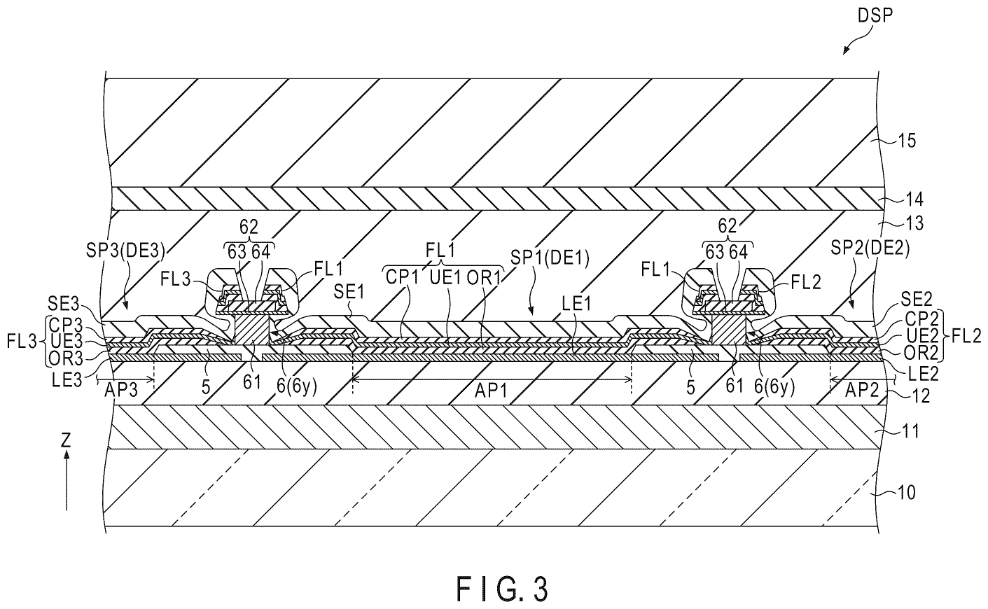

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, scanning line GL, signal line SL and power line PL shown in FIG. 1.

The circuit layer 11 is covered with an organic insulating layer 12. The organic insulating layer 12 functions as a planarization film which planarizes the irregularities formed by the circuit layer 11. Although not shown in the section of FIG. 3, all of the contact holes CH1, CH2 and CH3 described above are provided in the organic insulating layer 12.

The lower electrodes LE1, LE2 and LE3 are provided on the organic insulating layer 12. The rib 5 is provided on the organic insulating layer 12 and the lower electrodes LE1, LE2 and LE3. The end portions of the lower electrodes LE1, LE2 and LE3 are covered with the rib 5.

The partition 6 includes a conductive lower portion 61 provided on the rib 5 and an upper portion 62 provided on the lower portion 61. The upper portion 62 has a width greater than that of the lower portion 61. By this configuration, in FIG. 3, the both end portions of the upper portion 62 protrude relative to the side surfaces of the lower portion 61. This shape of the partition 6 may be called an overhang shape.

In the present embodiment, the upper portion 62 includes a first layer 63 and a second layer 64. The first layer 63 is provided on the lower portion 61. The second layer 64 is provided on the first layer 63.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. At least parts of the edge portions of the upper electrodes UE1, UE2 and UE3 are in contact with the side surface of the lower portion 61.

In the example of FIG. 3, a cap layer CP1 is provided on the upper electrode UE1. A cap layer CP2 is provided on the upper electrode UE2. A cap layer CP3 is provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a stacked layer body including the organic layer OR1, the upper electrode UE1 and the cap layer CP1 is called a thin film FL1. A stacked layer body including the organic layer OR2, the upper electrode UE2 and the cap layer CP2 is called a thin film FL2. A stacked layer body including the organic layer OR3, the upper electrode UE3 and the cap layer CP3 is called a thin film FL3.

The thin film FL1 is partly located on the upper portion 62. This portion is spaced apart from, of the thin film FL1, the portion located under the partition 6 (in other words, the portion which constitutes the display element DE1). Similarly, the thin film FL2 is partly located on the upper portion 62. This portion is spaced apart from, of the thin film FL2, the portion located under the partition 6 (in other words, the portion which constitutes the display element DE2). Further, the thin film FL3 is partly located on the upper portion 62. This portion is spaced apart from, of the thin film FL3, the portion located under the partition 6 (in other words, the portion which constitutes the display element DE3).

Sealing layers SE1, SE2 and SE3 which individually cover the display elements DE1, DE2 and DE3 are provided in subpixels SP1, SP2 and SP3, respectively. The sealing layer SE1 continuously covers the thin film FL1 and the partition 6 around subpixel SP1. The sealing layer SE2 continuously covers the thin film FL2 and the partition 6 around subpixel SP2. The sealing layer SE3 continuously covers the thin film FL3 and the partition 6 around subpixel SP3.

In the example of FIG. 3, the thin films FL1 and FL2 located on the partition 6 between subpixels SP1 and SP2 are spaced apart from each other. The thin films FL1 and FL3 located on the partition 6 between subpixels SP1 and SP3 are also spaced apart from each other.

In the example of FIG. 3, the end portions of the sealing layers SE1 and SE2 located on the partition 6 between subpixels SP1 and SP2 are spaced apart from each other. The end portions of the sealing layers SE1 and SE3 located on the partition 6 between subpixels SP1 and SP3 are also spaced apart from each other.

The sealing layers SE1, SE2 and SE3 are covered with a resin layer 13. The resin layer 13 is covered with a sealing layer 14. The sealing layer 14 is covered with a resin layer 15. The resin layers 13 and 15 and the sealing layer 14 are provided in at least the entire display area DA and partly extend in the surrounding area SA as well.

Another substrate comprising an optical element, a protective film, a cover glass or a touchpanel may be provided above the resin layer 15. This substrate may be attached to the resin layer 15 via a transparent adhesive layer such as optical clear adhesive (OCA).

Each of the organic insulating layer 12 and the resin layers 13 and 15 is formed of an organic insulating material. Each of the rib 5, the sealing layers SE1, SE2 and SE3 and the sealing layer 14 is formed of, for example, an inorganic insulating material such as silicon nitride (SiNx), silicon oxide (SiOx) or silicon oxynitride (SiON).

Each of the lower electrodes LE1, LE2 and LE3 comprises a reflective layer formed of, for example, silver (Ag), and a pair of conductive oxide layers covering the upper and lower surfaces of the reflective layer. Each conductive oxide layer may be formed of, for example, a transparent conductive oxide such as indium tin oxide (ITO), indium zinc oxide (IZO) or indium gallium zinc oxide (IGZO).

For example, each of the organic layers OR1, OR2 and OR3 comprises a multilayer structure consisting of a hole injection layer, a hole transport layer, an electron blocking layer, a light emitting layer, a hole blocking layer, an electron transport layer and an electron injection layer. Each of the organic layers OR1, OR2 and OR3 may comprise a tandem structure including a plurality of light emitting layers.

Each of the upper electrodes UE1, UE2 and UE3 is formed of, for example, a metal material such as an alloy of magnesium and silver (MgAg). For example, the lower electrodes LE1, LE2 and LE3 correspond to the anodes of the display elements DE1, DE2 and DE3. The upper electrodes UE1, UE2 and UE3 correspond to the cathodes of the display elements DE1, DE2 and DE3.

Each of the cap layers CP1, CP2 and CP3 is formed of, for example, a multilayer body of a plurality of transparent thin films. As the thin films, the multilayer body may include a thin film formed of an inorganic material and a thin film formed of an organic material. These thin films have refractive indices different from each other. The materials of the thin films constituting the multilayer body are different from the materials of the upper electrodes UE1, UE2 and UE3 and are also different from the materials of the sealing layers SE1, SE2 and SE3. It should be noted that at least one of the cap layers CP1, CP2 and CP3 may be omitted.

The lower portion 61 of the partition 6 is formed of, for example, aluminum (Al). The lower portion 61 may be formed of an aluminum alloy such as an aluminum-neodymium alloy (AlNd) or may comprise a multilayer structure consisting of an aluminum layer and an aluminum alloy layer. Further, the lower portion 61 may comprise a thin film formed of a metal material different from aluminum and an aluminum alloy under the aluminum layer or the aluminum alloy layer. This thin film can be formed of, for example, molybdenum (Mo).

The first layer 63 of the upper portion 62 is formed of, for example, a metal material such as titanium (Ti). The second layer 64 of the upper portion 62 is formed of, for example, an inorganic material such as silicon nitride, silicon oxide or silicon oxynitride. The second layer 64 may be formed of a conductive oxide such as ITO or may be formed of a metal material.

Common voltage is applied to the lower portion 61. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively.

When a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including a quantum dots which generates light exhibiting colors corresponding to subpixels SP1, SP2 and SP3 by the excitation caused by the light emitted from the light emitting layers.

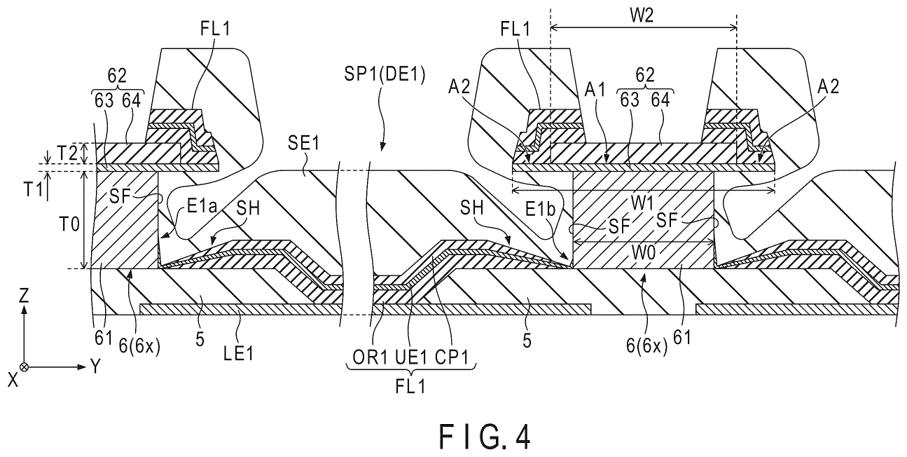

FIG. 4 is a schematic cross-sectional view of the display device DSP along the IV-IV line of FIG. 2 and shows subpixel SP1 and part of the partition 6 (first partitions 6x) around the subpixel. This section is taken along the Y-Z plane. In FIG. 4, the substrate 10, the circuit layer 11, the organic insulating layer 12, the resin layer 13, the sealing layer 14 and the resin layer 15 are omitted.

The lower portion 61 has width W0. The first layer 63 has width W1 greater than width W0 (W0<W1). By this configuration, the both end portions of the first layer 63 protrude from the side surfaces SF of the lower portion 61.

The second layer 64 has width W2 less than width W1 (W1>W2). By this configuration, the upper surface of the first layer 63 comprises a first area A1 which is covered with the second layer 64 and a pair of second areas A2 exposed from the second layer 64.

The second areas A2 are formed near the both end portions of the first layer 63, respectively. The first area A1 is located between these second areas A2 in the width direction of the partition 6 (in the example of FIG. 4, the second direction Y).

The thin film FL1 located on the upper portion 62 covers the second areas A2. More specifically, the second areas A2 are covered with the organic layer OR1 included in the thin film FL1. The thin film FL1 (organic layer OR1) also covers the side surfaces and part of the upper surface of the second layer 64.

Width W2 should be preferably greater than width W0 (W0<W2). By this configuration, as shown in FIG. 4, the both end portions of the second layer 64 protrude relative to the side surfaces SF of the lower portion 61 in the width direction. In this case, the strength of the upper portion 62 can be enhanced compared to a case where only the first layer 63 protrudes relative to the side surfaces SF.

The lower portion 61 has thickness TO. The first layer 63 has thickness T1 which is sufficiently less than thickness T0 (T0>T1). In the example of FIG. 4, the second layer 64 has thickness T2 greater than thickness T1 (T1<T2). By forming the second layer 64 so as to be thick in this manner, the strength of the upper portion 62 can be enhanced. However, thickness T2 does not necessarily have to be greater than thickness T1.

For example, the thickness (T1+T2) of the upper portion 62 is less than or equal to half of thickness TO of the lower portion 61. Thickness T1+T2 may be less than or equal to ⅓ of thickness TO. For example, thickness T0 is 900 nm, and thickness T1+T2 is 200 nm.

The thin film FL1 comprises a thickness decreasing portion SH in which the thickness gradually decreases toward the side surface SF. The thickness decreasing portion SH is located on the rib 5. In the thickness decreasing portion SH, the thickness of each of the organic layer OR1, the upper electrode UE1 and the cap layer CP1 gradually decreases.

The upper electrode UE1 comprises end portions E1a and E1b which are in contact with the side surfaces SF. Of the side surfaces SF, the areas located above the end portions E1a and E1b are covered with the sealing layer SE1. The sealing layer SE1 also covers the lower surface of the first layer 63.

In the example of FIG. 4, the end portion Ela is located on the upper side relative to the end portion E1b. Thus, the upper electrode UE1 is satisfactorily in contact with the side surface SF of the lower portion 61 of the partition 6 located on the left side of FIG. 4. The partition 6 located on the left side of FIG. 4 corresponds to the first partition 6x which overlaps the contact hole CH1 in FIG. 2.

The configuration of subpixels SP2 and SP3 and the partition 6 around the subpixels is similar to that of subpixel SP1 and the partition 6 around the subpixel in FIG. 4.

Now, this specification explains the manufacturing method of the display device DSP.

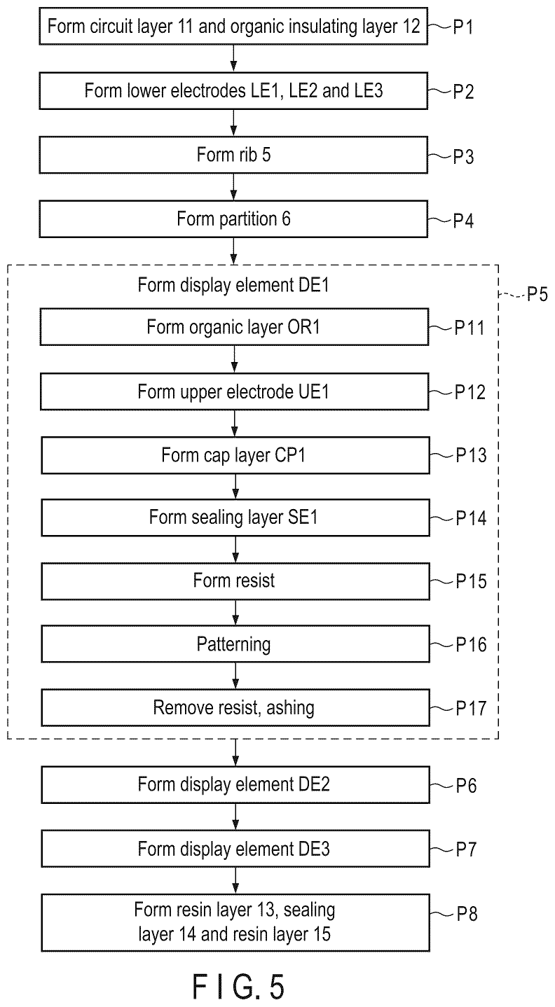

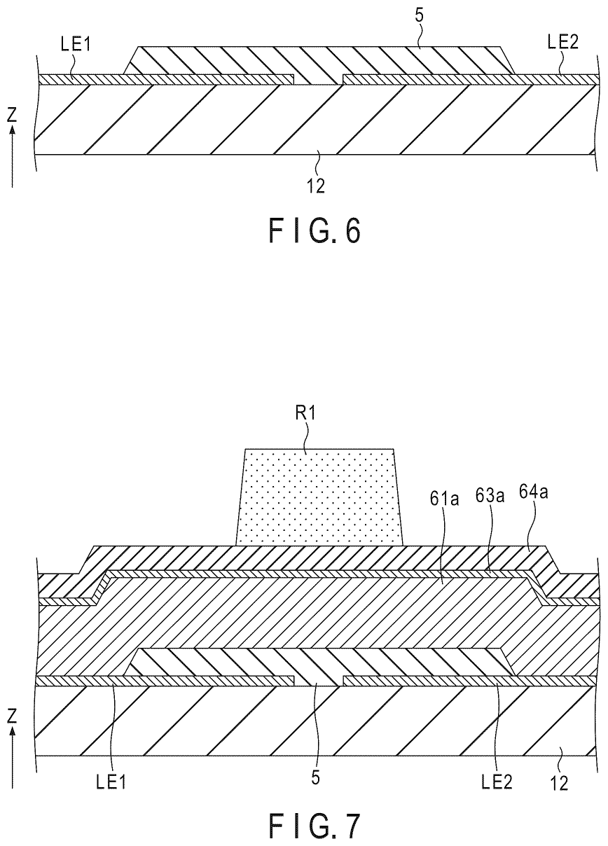

FIG. 5 is a flowchart showing an example of the manufacturing method of the display device DSP. Each of FIG. 6 to FIG. 18 is a schematic cross-sectional view showing part of the manufacturing process of the display device DSP. In FIG. 6 to FIG. 18, the substrate 10, the circuit layer 11 and the like are omitted.

To manufacture the display device DSP, first, the circuit layer 11 and the organic insulating layer 12 are formed on the substrate 10 (process P1).

After process P1, as shown in FIG. 6, the lower electrodes LE1, LE2 and LE3 are formed on the organic insulating layer 12 (process P22), and the rib which covers the lower electrodes LE1, LE2 and LE3 is formed (process P3). Subsequently, the partition 6 is formed on the rib 5 (process P4). The pixel apertures AP1, AP2 and AP3 may be formed before process P4 or may be formed after process P4.

In process P4, as shown in FIG. 7, first, a metal layer 61a which is the base of the lower portion 61 is formed on the rib 5. A first thin film 63a which is the base of the first layer 63 is formed on the metal layer 61a. A second thin film 64a which is the base of the second layer 64 is formed on the first thin film 63a. Further, a first resist R1 having a shape corresponding to the partition 6 is provided on the second thin film 64a.

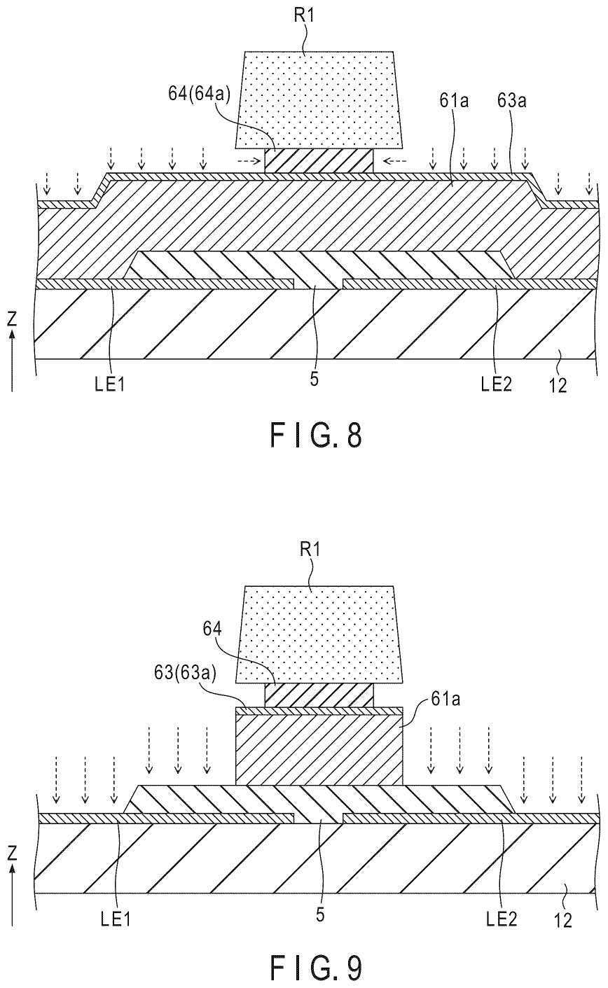

After the formation of the first resist R1, as shown in FIG. 8, of the second thin film 64a, the portion exposed from the first resist R1 is removed by wet etching. In this wet etching, the width of the second thin film 64a which remains below the first resist R1 is also reduced. By this process, the second layer 64 having a width less than that of the first resist R1 is formed.

Subsequently, anisotropic dry etching is performed, and as shown in FIG. 9, of the first thin film 63a, the portion exposed from the first resist R1 is removed. By this process, the first layer 63 having a width greater than that of the second layer 64 is formed.

Further, in this dry etching, of the metal layer 61a, the portion exposed from the first resist R1 is also removed. In the dry etching, of the metal layer 61a, the portion exposed from the first resist R1 may be thinly left. The dry etching for the metal layer 61a may be performed on a condition different from the dry etching for the first thin film 63a.

Subsequently, isotropic wet etching is applied. As shown in FIG. 10, the width of the metal layer 61a is reduced. By this process, the lower portion 61 having a width less than that of the first layer 63 is formed.

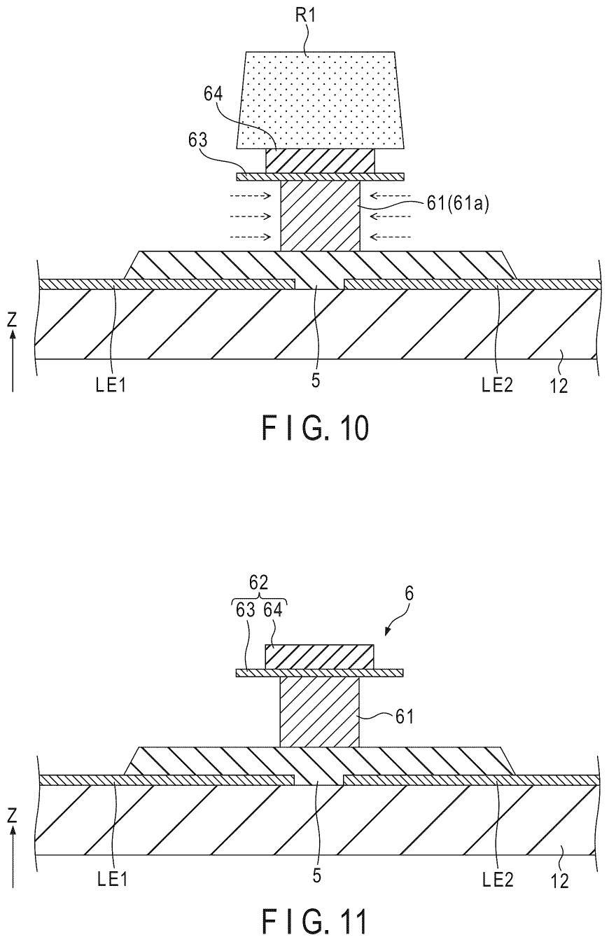

Subsequently, as shown in FIG. 11, the first resist R1 is removed. By the process described above, the partition 6 comprising the lower portion 61 and the upper portion 62 including the first layer 63 and the second layer 64 is formed.

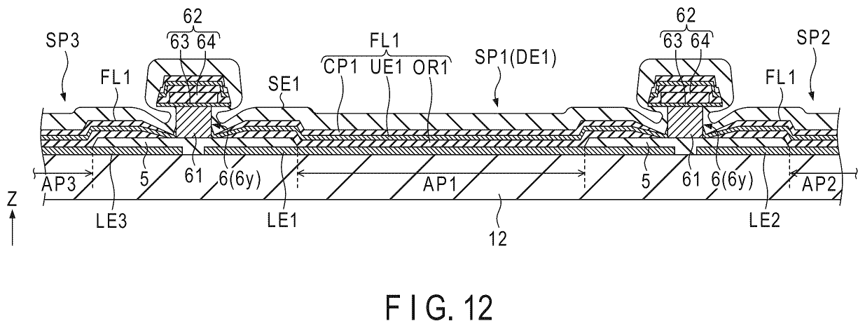

After process P4, the display element DE1 is formed (process P5). Specifically, as shown in FIG. 12, the organic layer OR1 is formed on the lower electrodes LE1, LE2 and LE3, the rib 5 and the partition 6 by vapor deposition (process P11). The upper electrode UE1 is formed on the organic layer OR1 by vapor deposition (process P12). The cap layer CP1 is formed on the upper electrode UE1 by vapor deposition (process P13). Further, the sealing layer SE1 which covers the thin film FL1 including the organic layer OR1, the upper electrode UE1 and the cap layer CP1 is formed by chemical vapor deposition (CVD) (process P14).

It should be noted that process P11 includes the processes of forming the thin films constituting the organic layer OR1 in series, such as the hole injection layer, the hole transport layer, the electron blocking layer, the light emitting layer, the hole blocking layer, the electron transport layer and the electron injection layer. Process P13 includes the processes of forming the thin films constituting the cap layer CP1 in series.

The thin film FL1 and the sealing layer SE1 are formed in at least the entire display area DA and are provided in subpixels SP2 and SP2 as well as subpixel SP1. The thin film FL1 is divided by the partition 6 having an overhang shape.

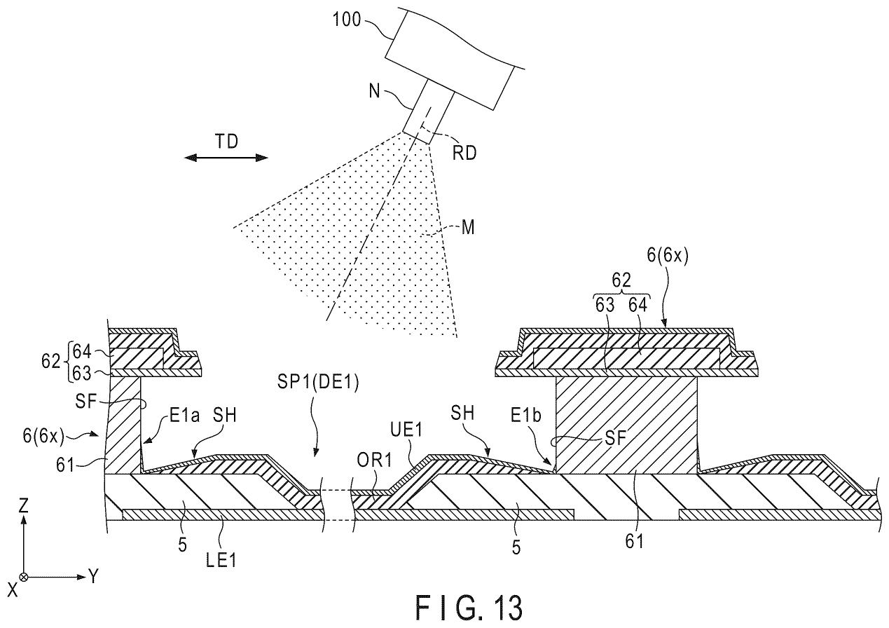

FIG. 13 is a schematic diagram showing an example of the evaporation method of the upper electrode UE1 and shows a state in which the evaporation material M of the upper electrode UE1 is emitted from the nozzle N of an evaporation source 100. It should be noted that the section of FIG. 13 corresponds to that of FIG. 4. Each of the partitions 6 shown in FIG. 13 corresponds to the first partition 6x shown in FIG. 2.

The evaporation source 100 and the substrate as the evaporation target are relatively moved in a conveyance direction TD parallel to, for example, the second direction Y. The evaporation material M is emitted from the nozzle N while spreading. The emission direction RD of the evaporation material M (or the extension direction of the nozzle N) inclines with respect to a third direction Z so as to face the partition 6 located on the left side of FIG. 13 (the first partition 6x overlapping the contact hole CH1). Thus, the evaporation material M is satisfactorily attached to the side surface SF of the left partition 6.

To the contrary, the evaporation material M which proceeds to the side surface SF of the partition 6 located on the right side of FIG. 13 is easily blocked by the upper portion 62. Thus, the amount of the evaporation material M attached to the side surface SF of the right partition 6 is less than that of the evaporation material M attached to the side surface SF of the left partition 6.

At the time of the vapor deposition of the organic layer OR1 and the cap layer CP1, they are formed by an evaporation method in which the nozzle N of the evaporation source 100 faces the third direction (Z direction). Thus, as shown in FIG. 4, each of the organic layer OR1 and the cap layer CP1 is provided such that the thickness gradually decreases toward the side surfaces SF in the same way on the both sides within subpixel SP1 in the Y-Z section. As the evaporation materials of the organic layer OR1, the upper electrode UE1 and the cap layer CP1 are blocked by the upper portion 62 at the time of vapor deposition, the thickness decreasing portion SH described above is formed on the rib 5.

When the evaporation method of FIG. 13 is used, the upper electrode UE1 is satisfactorily attached to the side surface SF of one of the partitions 6. In this manner, stable conduction can be assured between the upper electrode UE1 and the partition 6.

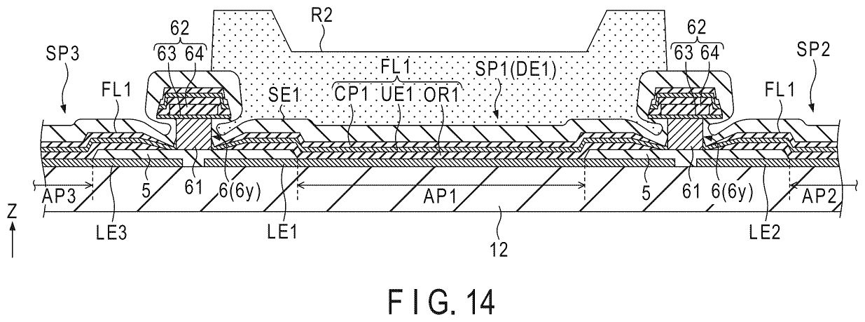

After process P14, as shown in FIG. 14, a second resist R2 is formed on the sealing layer SE1 (process P15). The second resist R2 covers subpixel SP1 and part of the partition 6 around the subpixel.

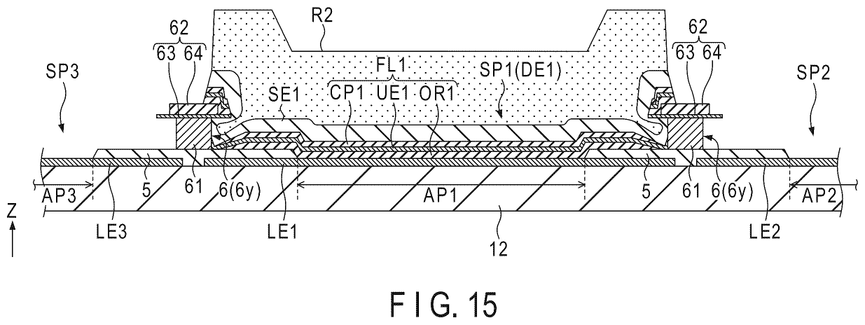

Subsequently, as shown in FIG. 15, the thin film FL1 and the sealing layer SE1 are patterned using the second resist R2 as a mask (process P16). This patterning includes dry etching for removing, of the sealing layer SE1, the portion exposed from the second resist R2. Further, this patterning includes dry etching and wet etching for removing, of the organic layer OR1, the upper electrode UE1 and the cap layer CP1, the portions exposed from the second resist R2 in series.

The upper electrode UE1 functions as an etching stopper in the dry etching of the sealing layer SE1. By this configuration, the corrosion of the rib 5 by the dry etching is prevented.

If the second layer 64 is formed of an inorganic insulating material similar to that of the sealing layer SE1, the second layer 64 could be also corroded in the dry etching of the sealing layer SE1. In this respect, the second layer 64 should be preferably formed of a material in which the etching rate in the dry etching is lower than that of the sealing layer SE1. For example, in a case where the sealing layer SE1 is formed of silicon nitride, when the second layer 64 is formed of silicon oxide or silicon oxynitride, the above relationship of the etching rate is realized.

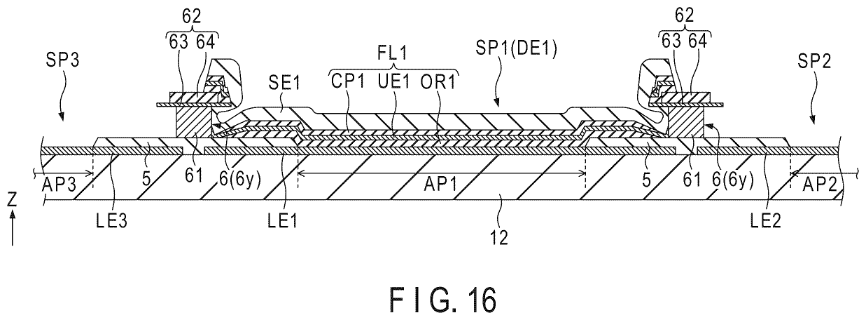

After process P16, the second resist R2 is removed by an exfoliation liquid, and the residue of the second resist R2, etc., is removed by asking (process P17). This process allows the acquisition of the substrate in which the display element DE1 and the sealing layer SE1 are formed in subpixel SP1 as shown in FIG. 16.

After the formation of the display element DE1, the display element DE2 is formed (process P6). The procedure of forming the display element DE2 is similar to processes P11 to P17. In other words, in a manner similar to that of processes P11 to P14, the organic layer OR2, the upper electrode UE2 and the cap layer CP2 are formed in order by vapor deposition, and the sealing layer SE2 is formed by CVD.

Subsequently, a resist is provided on the sealing layer SE2 in a manner similar to that of process P15. The organic layer OR2, the upper electrode UE2, the cap layer CP2 and the sealing layer SE2 are patterned in a manner similar to that of process P16. After this patterning, the resist is removed in a manner similar to that of process P17.

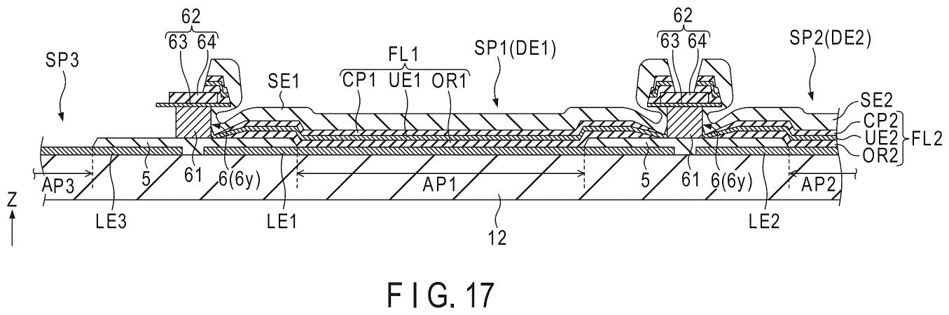

The process described above allows the acquisition of the following substrate. As shown in FIG. 17, in the substrate, the display element DE1 and the sealing layer SE1 are formed in subpixel SP1, and the display element DE2 and the sealing layer SE2 are formed in subpixel SP2.

After the formation of the display element DE2, the display element DE3 is formed (process P7). The procedure of forming the display element DE3 is similar to processes P11 to P17. In other words, in a manner similar to that of processes P11 to P14, the organic layer OR3, the upper electrode UE3 and the cap layer CP3 are formed in order by vapor deposition, and the sealing layer SE3 is formed by CVD.

Subsequently, a resist is provided on the sealing layer SE3 in a manner similar to that of process P15. The organic layer OR3, the upper electrode UE3, the cap layer CP3 and the sealing layer SE3 are patterned in a manner similar to that of process P16. After this patterning, the resist is removed in a manner similar to that of process P17.

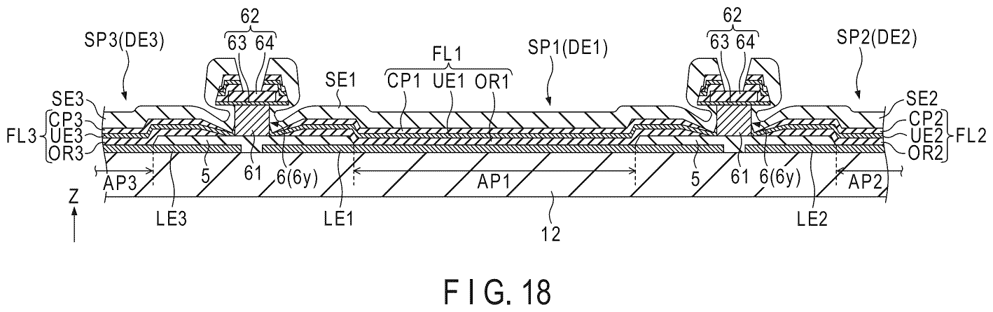

The above process allows the acquisition of the following substrate. As shown in FIG. 18, in the substrate, the display element DE1 and the sealing layer SE1 are formed in subpixel SP1, and the display element DE2 and the sealing layer SE2 are formed in subpixel SP2, and the display element DE3 and the sealing layer SE3 are formed in subpixel SP3.

After process P7, the resin layer 13, sealing layer 14 and resin layer 15 shown in FIG. 3 are formed in order (process P8). By this process, the display device DSP is completed. In the manufacturing process described above, this specification assumes a case where the display element DE1 is formed firstly, and the display element DE2 is formed secondly, and the display element DE3 is formed lastly. However, the formation order of the display elements DE1, DE2 and DE3 is not limited to this example.

In the present embodiment, the partition 6 having an overhang shape is provided in the boundaries of subpixels SP1, SP2 and SP3. In this case, the organic layers OR1, OR2 and OR3, the upper electrodes UE1, UE2 and UE3 and the cap layers CP1, CP2 and CP3 formed by vapor deposition are divided by the partition 6. By covering these divided layers with the sealing layers SE1, SE2 and SE3, the display elements DE1, DE2 and DE3 which are individually sealed can be obtained. In a case where the display elements DE1, DE2 and DE3 are individually sealed, even if a problem such as moisture penetration occurs in one of the display elements, the effect on the other display elements is prevented.

As described above, the upper electrode UE1 functions as an etching stopper in the dry etching of the sealing layer SE1, and the corrosion of the rib 5 is prevented. Therefore, the upper electrode UE1 needs to entirely cover the rib 5. However, as the evaporation material is blocked by the upper portion 62, the thickness decreasing portion SH described above (see FIG. 13) is generated near the lower portion 61. The upper electrode UE1 also becomes thin in the thickness decreasing portion SH. Thus, there is a possibility that the rib 5 cannot be sufficiently protected from the dry etching described above. In particular, when the emission direction RD of the evaporation material M from the evaporation source 100 inclines as explained with reference to FIG. 13, the upper electrode UE1 could become considerably thin on the end portion E1b side.

If an area in which the upper electrode UE1 is too thin or an area in which the upper electrode UE1 is not formed is generated, the rib 5 could be damaged by the dry etching of the sealing layer SE1. If such a damage is caused in subpixels SP2 and SP3, the thin films FL2 and FL3 which are formed subsequently may not be sufficiently sealed or may be cut.

As a method for satisfactorily covering the entire rib 5 with the upper electrode UE1, the upper portion 62 may be made thin. When the upper portion 62 is made thin, the area of the shadow of the evaporation source 100 is reduced in size. Thus, the thickness decreasing portion SH also becomes small. However, when the upper portion 62 is made thin, there is a possibility that the upper portion 62 is damaged because of strength poverty.

In the present embodiment, the upper portion 62 comprises the first layer 63 and the second layer 64 having a width less than that of the first layer 63. In this case, as the vicinity of the end portion of the upper portion 62 is thin, the thickness decreasing portion SH can be made small. To the contrary, as the vicinity of the center of the upper portion 62 is thick, the strength of the upper portion 62 can be increased. By these configurations, the yield of the manufacturing process of the display device DSP is improved.

The effects described above regarding the upper electrode UE1 are also obtained from the upper electrodes UE2 and UE3 in a similar manner. Thus, the configuration of the partition 6 in the present embodiment allows the upper electrodes UE2 and UE3 to satisfactorily cover the rib 5.

The configuration of the partition 6 is not limited to the disclosure of the present embodiment. For example, in the present embodiment, the upper portion 62 comprises a stacked layer structure consisting of two layers. However, the upper portion 62 may comprise a stacked layer structure consisting of three or more layers. In this case, the width of each layer constituting the upper portion 62 may decrease as the layer is located on the upper side.

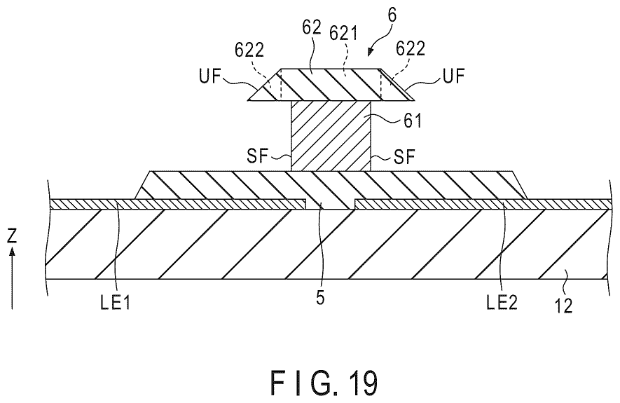

FIG. 19 is a schematic cross-sectional view of the partition 6 according to a modified example. In the example of FIG. 19, the upper portion 62 comprises a central portion 621 and taper portions 622 provided on the both end portions of the central portion 621.

The central portion 621 has a uniform thickness. In the example of FIG. 19, the central portion 621 has a width greater than that of the lower portion 61. However, the configuration is not limited to this example.

Each taper portion 622 is shaped so as to gradually become thinner with increasing distance from the central portion 621. The upper surface UF of each taper portion 622 inclines so as to go down with increasing distance from the central portion 621.

The upper portion 62 having this shape can be formed of, for example, an inorganic insulating material such as silicon nitride, silicon oxide or silicon oxynitride. The upper portion 62 may comprise a single-layer structure formed of an inorganic insulating material or may comprise a stacked layer structure consisting of a plurality of thin films formed of different materials.

In a case where the upper portion 62 comprises the taper portions 622 like the modified example, similarly, the area of the shadow of the evaporation source 100 is reduced in size at the time of the formation of the upper electrode UE1, etc. Thus, the rib 5 can be satisfactorily covered with the upper electrode UE1.

All of the display devices and manufacturing methods thereof that can be implemented by a person of ordinary skill in the art through arbitrary design changes to the display device and manufacturing method thereof described above as the embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiment by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiment and are self-explanatory from the descriptions of the specification or can be arbitrarily conceived by a person of ordinary skill in the art are considered as the effects of the present invention as a matter of course.

What is claimed is:

1. A display device comprising:
a lower electrode;
a rib comprising a pixel aperture which overlaps the lower electrode;
a partition which includes a lower portion provided on the rib, a first layer provided on the lower portion and protruding from a side surface of the lower portion, and a second layer provided on the first layer and having a width less than a width of the first layer;
an organic layer which covers the lower electrode through the pixel aperture and emits light based on application of voltage; and
an upper electrode which covers the organic layer and is in contact with the side surface of the lower portion.

2. The display device of claim 1, wherein
an upper surface of the first layer comprises:
a first area covered with the second layer; and
a second area exposed from the second layer.

3. The display device of claim 2, wherein
the second area is covered with part of the organic layer.

4. The display device of claim 3, wherein
at least a part of an upper surface of the second layer is covered with another part of the organic layer.

5. The display device of claim 2, wherein
the second area includes a pair of second areas, and
the first area is located between the second areas in a width direction of the partition.

6. The display device of claim 1, wherein
the width of the second layer is greater than a width of the lower portion.

7. The display device of claim 6, wherein
both end portions of the second layer in a width direction of the partition protrude relative to the side surfaces of the lower portion in the width direction.

8. The display device of claim 1, wherein
the second layer is thicker than the first layer.

9. The display device of claim 1, wherein
a total thickness of the first layer and the second layer is less than or equal to half of a thickness of the lower portion.

10. The display device of claim 1, wherein
the first layer is formed of a metal material, and
the second layer is formed of an inorganic insulating material.

11. The display device of claim 1, wherein
the first layer is formed of a metal material, and
the second layer is formed of a conductive oxide.

12. The display device of claim 1, wherein
each of the first layer and the second layer is formed of a metal material.

13. The display device of claim 1, further comprising a sealing layer which covers a thin film including the organic layer and the upper electrode, wherein
the rib and the sealing layer are formed of inorganic insulating materials.

14. The display device of claim 13, wherein
the thin film further includes an optical adjustment layer located between the upper electrode and the sealing layer.

15. A manufacturing method of a display device, the method including:
forming a lower electrode;
forming a rib comprising a pixel aperture which overlaps the lower electrode;
forming a partition which includes a lower portion provided on the rib, a first layer provided on the lower portion and protruding from a side surface of the lower portion, and a second layer provided on the first layer and having a width less than a width of the first layer;
forming an organic layer which covers the lower electrode through the pixel aperture and emits light based on application of voltage; and
forming an upper electrode which covers the organic layer and is in contact with the side surface of the lower portion.

16. The manufacturing method of claim 15, wherein
the forming the partition includes:
forming a metal layer on the rib;
forming a first thin film on the metal layer;
forming a second thin film on the first thin film;
providing a first resist having a shape corresponding to the partition on the second thin film;
forming the second layer having a width less than a width of the first resist by removing, of the second thin film, a portion exposed from the first resist by etching and reducing a width of the second thin film;
forming the first layer by removing, of the first thin film, a portion exposed from the first resist by etching; and
forming the lower portion having a width less than the width of the first layer by removing, of the metal layer, a portion exposed from the first resist by etching and reducing a width of the metal layer.

17. The manufacturing method of claim 15, further including:
forming a sealing layer which covers a thin film including the upper electrode and the organic layer;
providing a second resist on the sealing layer; and
removing, of the sealing layer and the thin film, portions exposed from the second resist.
